(19) United States
(12) Patent Application Publication
(10) Pub. No.: US 2006/0021740 A1
(43) Pub. Date: Feb. 2, 2006

(54) Vacuum condenser heat sink

(76) Inventor: Richard Chi-Hsueh, Cary, NC (US)

Correspondence Address: RICHARD CHI-HSUEH, 102 WHISPERWOOD DR, CARY, NC, 27511, US

(21) Appl. No.: 11/166,868

(22) Filed: Sep. 23, 2005

Related U.S. Application Data
(60) Provisional application No. 60/598,204, filed on Jul. 30, 2004.

(51) Int. Cl. H05K 7/20

(52) U.S. Cl. 165/104.33; 165/80.3; 361/700

(57) ABSTRACT

The Vacuum Condenser Heat Sink has many thin metal fins on the top, which makes it easier for the fan to blow way the heat. But the key to this heat sink is that there is a mini condensation cycle inside the heat sink that speeds up the heat transfer from the over heated material

This invention is based on the concept of the common heat sink used on electronics and computers. The improvement made to the metal fin heat sink enables the vacuum condenser (VC) heat sink to increase the speed up to 25 times faster to conduct heat away as the same size metal fin heat sink and 2-3 times faster to dissipate heat.

The VC heat sink can lower the heat source to the safest temperature in very a short period of time. At this rate of dissipating heat away from the electronics such advantages as increases the usage period, extends uses of electronics, and expends abilities of computers will be in good interest for high tech developments.

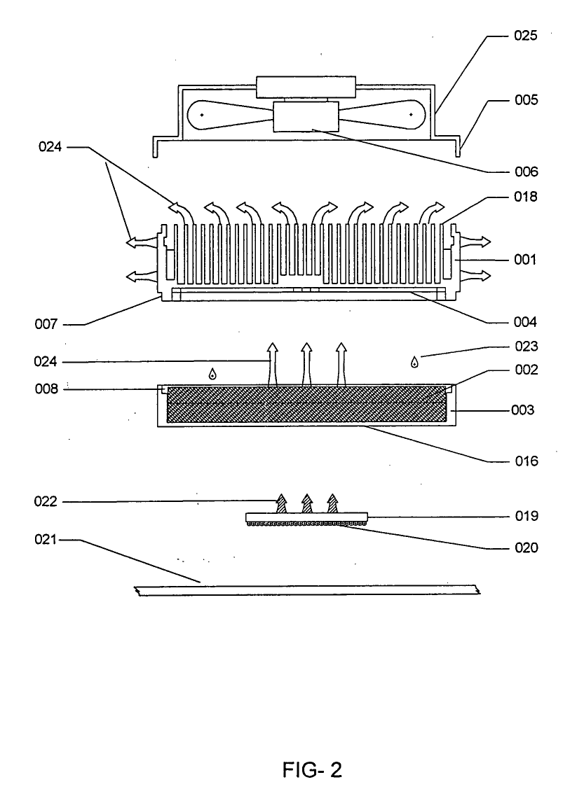

Shown in FIG. 2 the fin plate 001 has a bottom concave 004, when the fin plate is assembled with the concave space 017 of the base plate 003 forms a inner chamber 004. The tongue 007 on the fin plate 001 ensures a perfect seal when assembled with the groove 008 of the base plate 003. The bottom 016 of base plate 003 is a flat surface, is in contact with the CPU 019 and transfers the heat from the CPU to the micro wire rods 002 in the inner chamber. The vacuum chamber contains the micro metal rod 002 and the evaporative liquid 023. When the heat is transferred from the CPU to the vacuum chamber, it causes the liquid to evaporate and condenses which produces a convection effect that speeds up the heat transferring process to the metal fins 018. Then the fan will dissipate the heat away from the metal fins efficiently.

The heat sink is produced from aluminum or copper alloys, such metals have high conducting quality. The fins 018 are manufactured by extruding, both base plate 003 and the bottom concave 004 by using milling process.

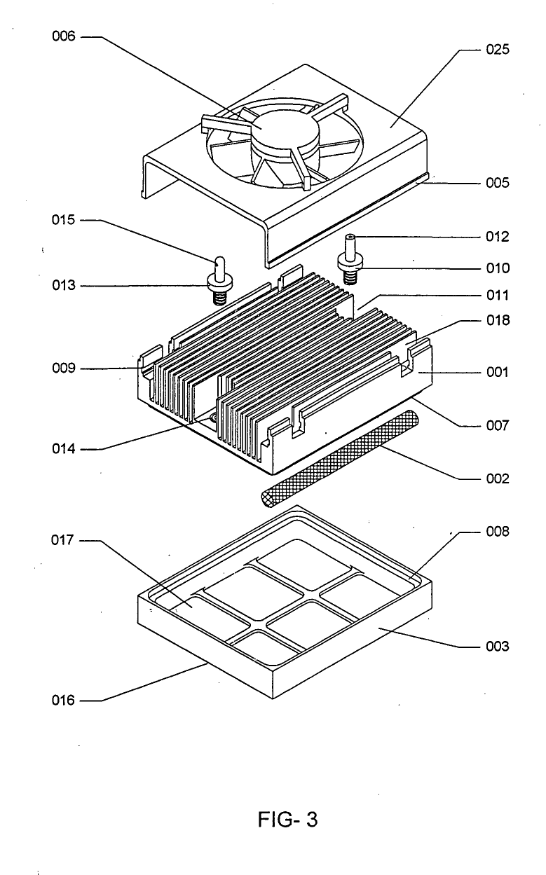

The fan 004 at top is used for dissipating heat away from the metal fins 018. The tongue 005 on the fan used for assembling the groove 009 in fin plate 001. The metal fins 018 are used to increase surface area. From FIG. 3 the two drilled holes 011 and 014 are for insertion head 010 and vacuuming head 014 respectively.

The micro metal wire rods 002 are micro-wires woven like fabric and then roll up into a rod. These rods have capillary effect and they fill the chamber 004. Both plates can be compressed together or wielded to create a leak-free seal. A test is performed to insure that neither air nor liquids can escape from the seal. Next the soluble, evaporative liquid 023 are inserted through the hole on the insertion head. After inserting enough amounts of the evaporative liquid to moisten the micro metal rods, the insertion hole is seal to prevent leakage.

Now the chamber is ready to be vacuumed from vacuuming head 015 and sealed after the task is done. The purpose of vacuuming the chamber is that any liquid under the state of vacuum will evaporate 90-100 times faster than at normal atmosphere pressure. Thus the name of this invention, the vacuum condenser heat sink (the VC heat sink).

Detailed explanation of FIG. 2: The CPU die 019 on the PCB 021 emits large amounts of heat 022 when at work. The bottom of the base plate 016 absorbs the heat from CPU and transfers the heat to the inner chamber 004. When the evaporative liquid 023 in the micro wire rods 002 will start to evaporate 024, and transmit the heat to the metal fins 018 of the fin plate 001. The fan 006 will disparate the heat 024 away from the metal fins.

The most important innovation of this invention is the capillary pumped loop effect in the inner, chamber 004. When heated the liquid will evaporate upward, bringing the heat absorbed in from the CPU along with it. The fan cools the metal fins, the liquid will condense and ready to be evaporated again. This cycle enables the heat sink to dissipate more heat than the common heat sinks. It operates without any additional outside forces, and never needs to replace or add the liquid in the chamber.

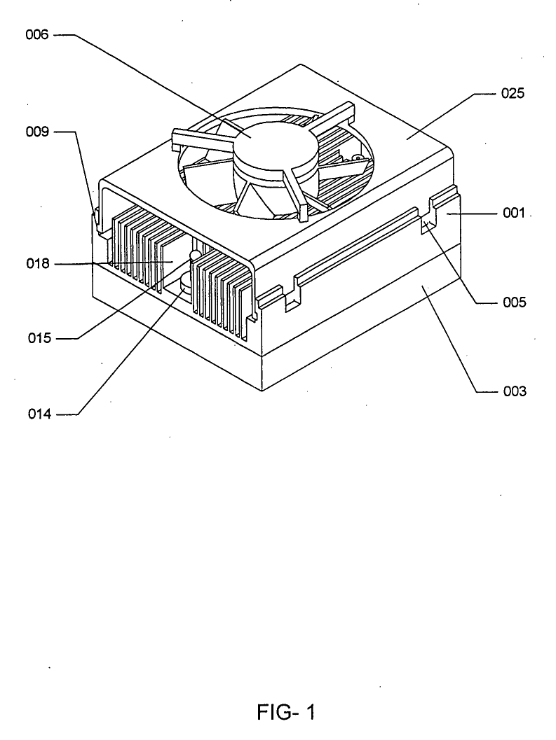

FIG. 1 is a perspective view of the fully assembled vacuum condenser heat sink.

FIG. 2 is a cross-section view of how the vacuum condenser heat sink works.

FIG. 3 is an exploded view with all the parts in the vacuum condenser heat sink.

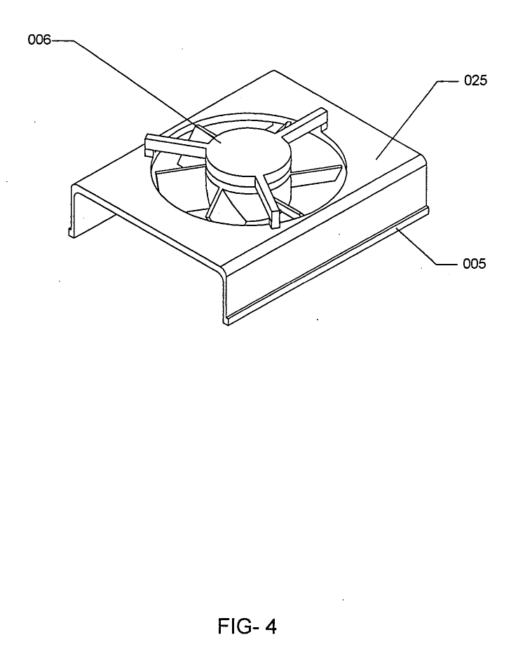

FIG. 4 is a perspective view of the fan for dissipating heat.

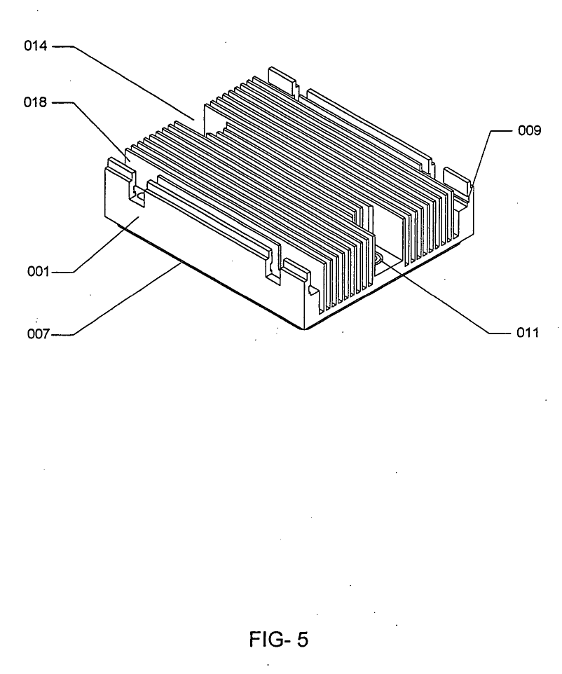

FIG. 5 is a perspective view of the fin plate.

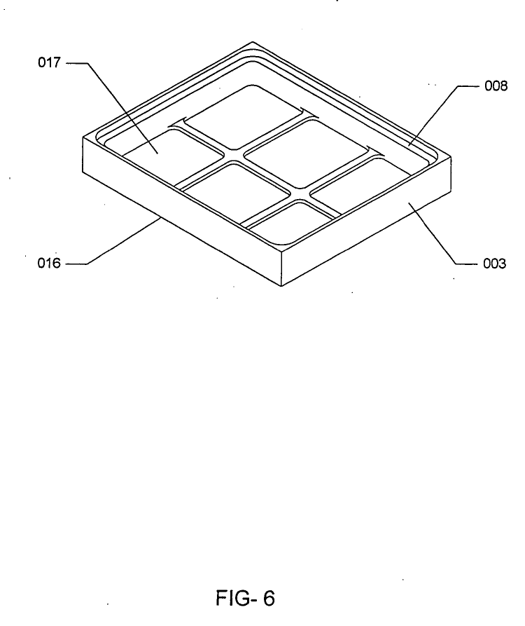

FIG. 6 is a perspective view of the base plate of the vacuum condenser heat sink.

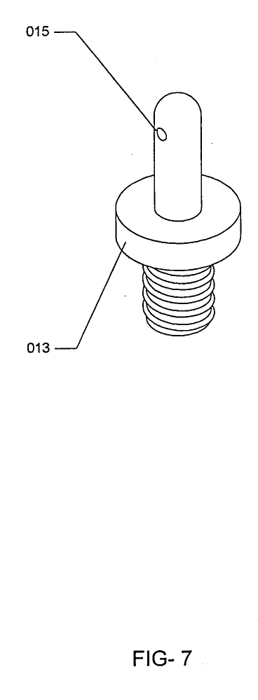

FIG. 7 is a perspective view of the head for vacuuming of inner chamber.

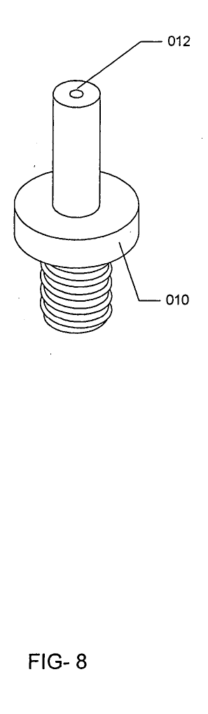

FIG. 8 is a perspective view of the head which liquid is inserted.

001 fin plate of the vacuum condenser heat sink

002 micro wire woven and rolled into a rod that has capillary ability.

003 base plate of the vacuum condenser heat sink.

004 inner chamber created by the fin plate and base plate.

005 fan tongue

006 fan for dissipate heat away from the heat sink.

007 fin plate tongue for sealing base plate.

008 base plate groove for sealing base plate.

009 groove for fan's tongue.

010 head for inserting the evaporative liquid.

011 drilled hole on fin plate 007 for placing 010.

012 hole for inserting the evaporative liquid.

013 head for vacuuming.

014 drilled hole for placing of 013 on the fin plate.

015 hole for vacuuming.

016 bottom of the base plate.

017 inner space of base plate.

018 metal fins.

019 CPU.

020 pins for the mounting the CPU on to the PCB.

021 PCB

022 heat produced by CPU at work.

023 soluble, concentrated, and evaporative liquid.

024 evaporate liquid expanding in the vacuum chamber.

025 fan for dissipate heat away from the heat sink.

1. The capillary pumped loop effect appled in a vacuumed inner chamber to speed up the condensation process, whichenables the fan to disspate heat more efficiently.
